(19) United States
(12) Patent Application Publication
(10) Pub. No.: US 2015/0333777 A1
(43) Pub. Date: Nov. 19, 2015

(54) REDUNDANT INFORMATION COMPRESSION METHOD, AND SEMICONDUCTOR DEVICE

(71) Applicant: SOCIONEXT INC., Yokohama-shi (JP)

(72) Inventor: Hideo AKIYOSHI, Nishitama (JP)

(21) Appl. No.: 14/701,126

(22) Filed: Apr. 30, 2015

(30) Foreign Application Priority Data
May 13, 2014 (JP) 2014-099615

(51) Int. Cl. H03M 13/00; G06F 11/10

(52) U.S. Cl. CPC H03M 13/6312; G06F 11/1076

(57) ABSTRACT

A redundancy information compression method is configured to compress redundancy information among a plurality of macros for which redundancy processing is performed. The redundancy information compression method includes setting faulty bit position information, included in the redundancy information, for a macro of the plurality of macros including a faulty bit, the faulty bit position information indicating a position of the faulty bit included in the macro; and organizing macro numbers, included in the redundancy information, of macros of the plurality of macros having the same faulty bit position information as the set faulty bit position information together.

### CROSS-REFERENCE TO RELATED APPLICATION

This application is based upon and claims the benefit of priority of the prior Japanese Patent Application No. 2014-099615, filed on May 13, 2014, the entire contents of which are incorporated herein by reference.

### FIELD

The embodiments discussed herein are related to a redundant information compression method, and a semiconductor device.

### BACKGROUND

Redundancy information has been conventionally stored without being compressed. As semiconductor manufacturing technology advances, for example, the number and size of SRAM (Static Random Access Memory) macros packaged in a semiconductor chip increase and consequently the amount of redundancy information increases.

For example, an embedded SRAM is made up of multiple SRAM macros, is packaged in the semiconductor chip (die) in which integrated circuits such as ASIC (Application Specific Integrated Circuit) and processors are packaged and is used as a cache memory or an image memory. Note that a macro is a functional block and an SRAM macro is a memory block including an SRAM memory array.

As stated above, the number and capacity of SRAM macros packaged in a semiconductor chip, for example, are increasing with the advance in semiconductor manufacturing technology. Since such SRAM macros in general include faulty bits due to manufacturing processes and other factors, redundancy processing is performed.

In other words, redundancy information including, for example, the number of an SRAM macro (the macro number) that includes a faulty bit among a plurality of SRAM macros and information indicating the position of the faulty bit in the SRAM macro is provided to recover the faulty bit.

Redundancy information is often stored in electronic fuses (eFUSE), which are difficult to miniaturize, and therefore there is the problem of the area being occupied by the electronic fuses in a semiconductor chip.

To address this problem, attempts have been made to compress redundancy information to reduce the size of area needed to store the information. For example, a method has been proposed in which a macro number and faulty bit position information are stored in pairs to compress redundancy information.

For example a method of compressing redundancy information has been proposed in which a macro number and faulty bit position information are paired and stored as described above, it has been difficult to address the increase in the amount of redundancy information in these years by the method alone.

In other words, the number and capacity of macros packaged in a semiconductor chip have been significantly increased and the amount of redundancy information has considerably increased accordingly. Therefore, compression of redundancy information merely by pairing a macro number and faulty bit position information leaves the problem that redundancy information occupies a large storage area in a semiconductor chip and decreases the area that can be used for the primary circuitry.

Incidentally, in the past, various redundancy information compression methods for compressing redundancy information to reduce the area occupied by the redundancy information and semiconductor devices to which the methods are applied have been proposed.

Patent Document 1: Japanese Laid-open Patent Publication No. 2007-193879

Patent Document 2: Japanese Laid-open Patent Publication No. 2009-043328

Patent Document 3: Japanese Laid-open Patent Publication No. 2002-261599

Patent Document 4: Japanese Laid-open Patent Publication No. 2008-257474

Patent Document 5: Japanese Laid-open Patent Publication No. 2010-232712

### SUMMARY

According to an aspect of the embodiments, there is provided a redundancy information compression method configured to compress redundancy information among a plurality of macros for which redundancy processing is performed.

The redundancy information compression method includes setting faulty bit position information, included in the redundancy information, for a macro of the plurality of macros including a faulty bit, the faulty bit position information indicating a position of the faulty bit included in the macro; and organizing macro numbers, included in the redundancy information, of macros of the plurality of macros having the same faulty bit position information as the set faulty bit position information together.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram for illustrating redundancy information;

FIG. 2 is a diagram for illustrating the relationship between the number of macros for which redundancy has been performed and the proportion of the macros;

FIG. 3A and FIG. 3B are diagrams for illustrating an example of a redundancy information compression method;

FIG. 4 is a block diagram for illustrating an example of a semiconductor device to which the redundancy information compression method illustrated in FIG. 3A and FIG. 3B is applied;

FIG. 5 is a diagram for illustrating a relevant part of the semiconductor device illustrated in FIG. 4;

FIG. 6A and FIG. 6B are diagrams for illustrating a first exemplary embodiment of a redundancy information compression method;

FIG. 7 is a block diagram for illustrating an example of a semiconductor device to which the redundancy information compression method illustrated in FIG. 6A and FIG. 6B is applied;

FIG. 8 is a diagram for illustrating a relevant part of the semiconductor device illustrated in FIG. 7;

FIG. 9 is a state transition diagram for illustrating an example of a separation identifying circuit in the semiconductor device illustrated in FIG. 7 and FIG. 8;

FIG. 10 is a block diagram for illustrating an example of an SRAM macro in the semiconductor device illustrated in FIG. 7;

FIG. 11 is a block diagram for illustrating an example of a selector in the semiconductor device illustrated in FIG. 7;

FIG. 12A and FIG. 12B are diagrams for illustrating a second exemplary embodiment of a redundancy information compression method;

FIG. 13 is a block diagram for illustrating an example of a semiconductor device to which the redundancy information compression method illustrated in FIG. 12A and FIG. 12B is applied;

FIG. 14 is a diagram for illustrating a relevant part of the semiconductor device illustrated in FIG. 13;

FIG. 15 is a state transition diagram for illustrating an example of a separation identifying circuit in the semiconductor device illustrated in FIG. 13 and FIG. 14; and

FIG. 16 is a diagram for illustrating an advantageous effect of the redundancy information compression method of the second exemplary embodiment.

### DESCRIPTION OF EMBODIMENTS

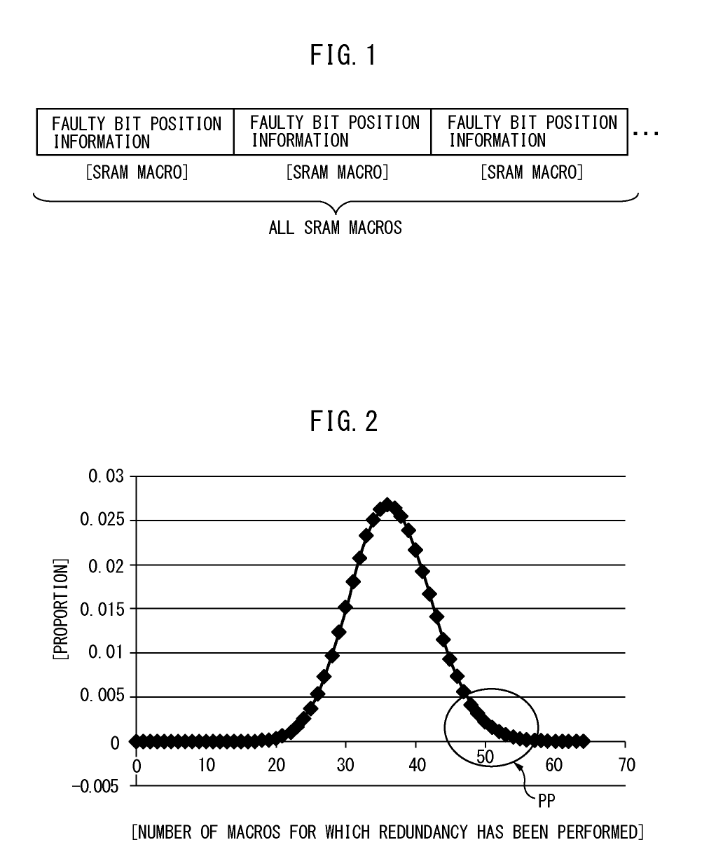

First, before describing embodiments of a redundancy information compression method and a semiconductor device in detail, redundancy information will be described first with reference to FIG. 1 and FIG. 2, and an example of the redundancy information compression method, an example of the semiconductor device and problems with the method and semiconductor device will be described.

FIG. 1 is a diagram for illustrating redundancy information and for illustrating processing of redundancy information without compression. Since redundancy for SRAM macros is performed on a macro-by-macro basis, information indicating faulty bit positions (for example approximately 5 to 16 bits) in the macro is stored for each macro, in one to one relationship as illustrated in FIG. 1 when compression is not performed.

In other words, as many pieces of faulty bit position information as the number of macros are stored, as a result the amount of the information significantly increases as the number of macros increases even though the number of macros for which redundancy is performed is small, for example.

As stated above, redundancy information (as many pieces of faulty bit position information as the number of macros) is stored in an electronic fuse, for example. The electronic fuse is difficult to miniaturize in spite of the advancement of semiconductor manufacturing technology and the area occupied by the electronic fuses (redundancy information) in semiconductor chips remains a problem.

In other words, as the number and capacity of SRAM macros packaged in a semiconductor chip increase, the amount of redundancy information significantly increases and the storage area of the redundancy information in the semiconductor chip increases to decrease the area that can be used for the primary circuitry.

FIG. 2 is a diagram for illustrating the relationship between the number of macros for which redundancy is performed and the proportion of the macros and illustrating the relationship between the number of macros for which redundancy is actually performed (the number of macros for which redundancy has been performed) and the proportion (ratio) when 1024 SRAM macros (redundant macros) are packaged as an example.

In other words, FIG. 2 illustrates the relationship between the number of macros for which redundancy has been performed (on the horizontal axis) and the proportion of the macros (on the vertical axis) in an example where the capacity of an SRAM macro is 512 kilobits (Kbits), the number of the SRAM macros packaged is 1024, and the proportion of faulty cells is 1/10,000,000 ( 1/10 Mbits). The capacity of a macro in the example is 4 kw×128 bits=512 Kbits.

As indicated by symbol PP in in FIG. 2, the number of macros for which redundancy is performed is approximately 50 or less out of the 1024 macros packaged, for example. In other words, the number of macros for which redundancy processing is actually performed is limited and the proportion of such macros is low even when the number of macros increases. By taking advantage of the fact that the number of macros for which redundancy processing is not performed is large, redundancy data (redundancy information) can be compressed.

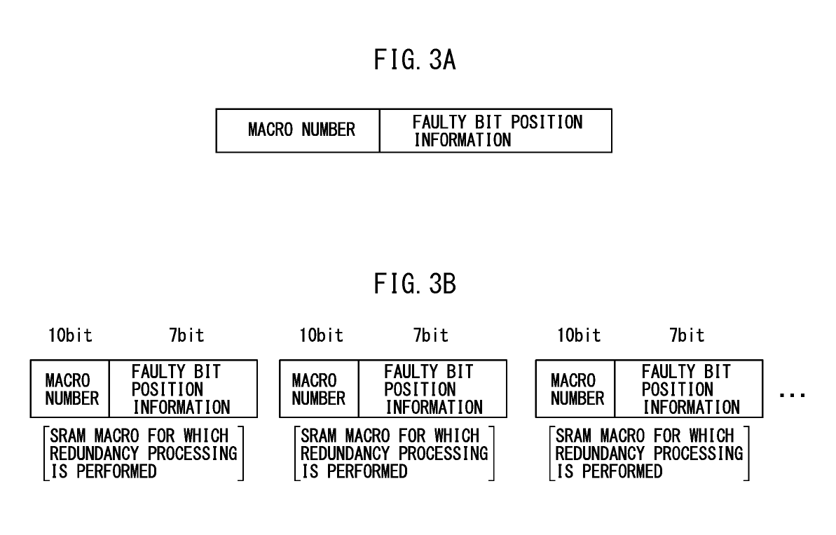

FIG. 3A and FIG. 3B are diagrams for illustrating an example of a redundancy information compression method. FIG. 3A illustrates a pair of macro number and faulty bit position information (faulty bit position) and FIG. 3B illustrates pairs of macro number and faulty bit position information for a plurality of SRAM macros (that include a faulty bit) for which redundancy processing is performed.

In the redundancy information compression method illustrated in FIG. 3A and FIG. 3B, redundancy information is compressed by assigning a macro number (serial number) to each of a plurality of macros and storing sets (pairs) of macro number (for example 10 bits) and faulty bit position information (for example 7 bits).

In other words, since redundancy processing is actually performed for at most about 50 out of 1024 SRAM macros, for example, as stated previously, redundancy information can be compressed by pairing macro numbers with faulty bit position information for the SRAM macros for which the redundancy processing is performed.

However, as the number of SRAM macros increases, the redundancy information compression method illustrated in FIG. 3A and FIG. 3B may not be able to sufficiently compress redundancy information because the method stores a macro number and faulty bit position information in pairs (17 bits) for one redundant macro (one redundant SRAM cell).

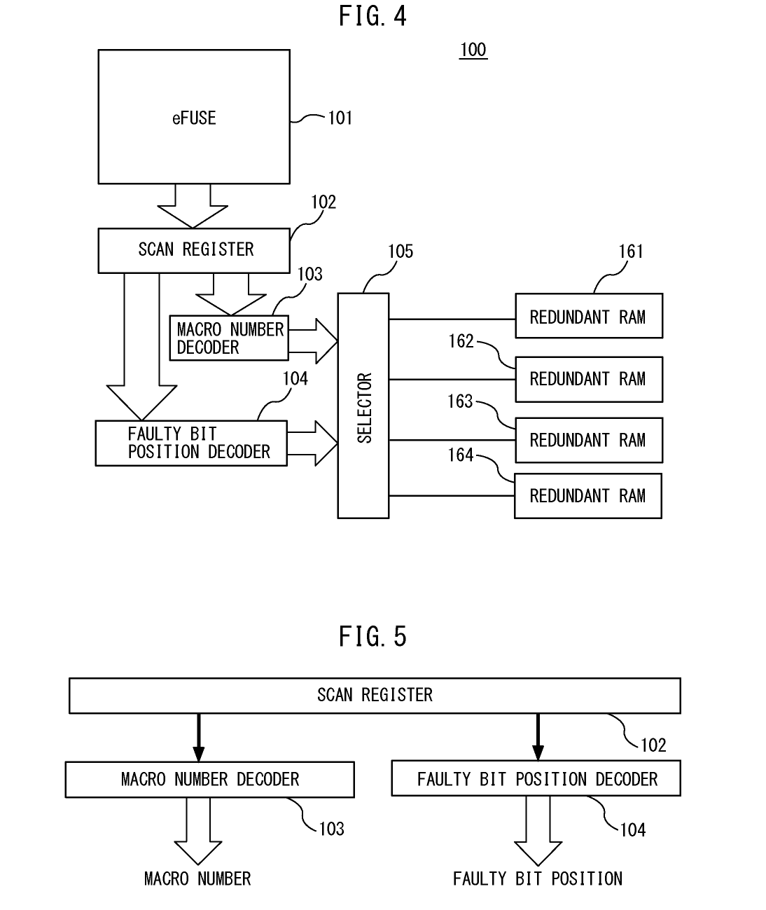

FIG. 4 is a block diagram illustrating an example of a semiconductor device to which the redundancy information compression method illustrated in FIG. 3A and FIG. 3B is applied and focusing on components that perform redundancy processing in an embedded SRAM (semiconductor storage device), which is an example of the semiconductor device.

As illustrated in FIG. 4, the semiconductor device 100 includes an electronic fuse (eFUSE: a redundancy information storage unit) 101, a scan register 102, a macro number decoder 103, a faulty bit position decoder 104, a selector 105 and SRAM macros 161-164.

The electronic fuse 101 stores redundancy information (pairs of macro number and faulty bit position) as illustrated in FIG. 3B for SRAM macros for which redundancy processing is performed, for example, and the scan register 102 reads the redundancy information stored in the electronic fuse 101 in sequence and holds the read redundancy information.

FIG. 5 is a diagram for illustrating a relevant part of the semiconductor device illustrated in FIG. 4 and depicting the scan register 102, the macro number decoder 103 and the faulty bit position decoder 104 extracted from FIG. 4.

The macro number decoder 103 receives an output (a pair of macro number and faulty bit position information) from the scan register 102, decodes the macro number and outputs the decoded macro number. The faulty bit position decoder 104 receives an output from the scan register 102, decodes faulty bit position information, and outputs the decoded faulty bit position information.

The selector 105 receives the macro numbers from the macro number decoder 103 and the faulty bit position information from the faulty bit position decoder 104 and performs redundancy processing in the SRAM macros 161-164 according to the macro numbers and the faulty bit position information in sequence.

In other words, the selector 105 identifies the position of a faulty bit in the SRAM macro 161, for example, and performs switching from the input/output circuit (I/O) including the faulty bit to a redundant RAM region provided beforehand (I/O redundancy).

The redundancy processing is not limited to I/O level redundancy processing; for example column redundancy (including I/O redundancy) using one or more bit lines as a unit or row redundancy using one or more word lines as a unit, or any other known redundancy may be used. This is applicable not only to the example in FIG. 3A to FIG. 5; various types of redundancy processing can be applied also to exemplary embodiments described later in detail.

With the advancement of the semiconductor manufacturing technology, the number and capacity of SRAM macros packaged in a semiconductor chip are considerably increasing. In the case of the 28-nm generation, for example, about 3000 macros may be packaged.

In other words, about 3000 macro numbers per chips or more macro numbers will be used in the future. On the other hand, the amount of faulty bit position information, i.e., the number of faulty bit positions in each SRAM macro may be 128 positions (bits) or at most 256 bits.

For a chip in which 1000 to 3000 SRAM macros, for example, are packaged, the redundancy information compression method that pairs a macro number with faulty bit position information as described with reference to FIG. 3A to FIG. 5 may not achieve adequate compression of redundancy information.

For example, the number and capacity of SRAM macros packaged in each semiconductor chip are significantly increasing and the amount of redundancy information is considerably increasing accordingly. Redundancy information compressed simply by pairing a macro number with faulty bit position information will occupy a large memory area in a semiconductor chip and decreases the area that can be used for primary circuitry.

The exemplary embodiments described below in detail is not limited to application to an embedded SRAM made up of a plurality of SRAM macros and can be applied to a wide variety of semiconductor storage devices including, for example, a plurality of memory macros, such as a DRAM.

Furthermore, the exemplary embodiments are applicable not only to a semiconductor storage device including a plurality of memory macros but also a wide variety of semiconductor devices that include a plurality of circuit macros that have an identical configuration, for example. A plurality of circuit macros to which the exemplary embodiments are applicable are circuit macros that have an identical configuration and for which redundancy processing can be performed using redundancy information including macro numbers and faulty bit position information.

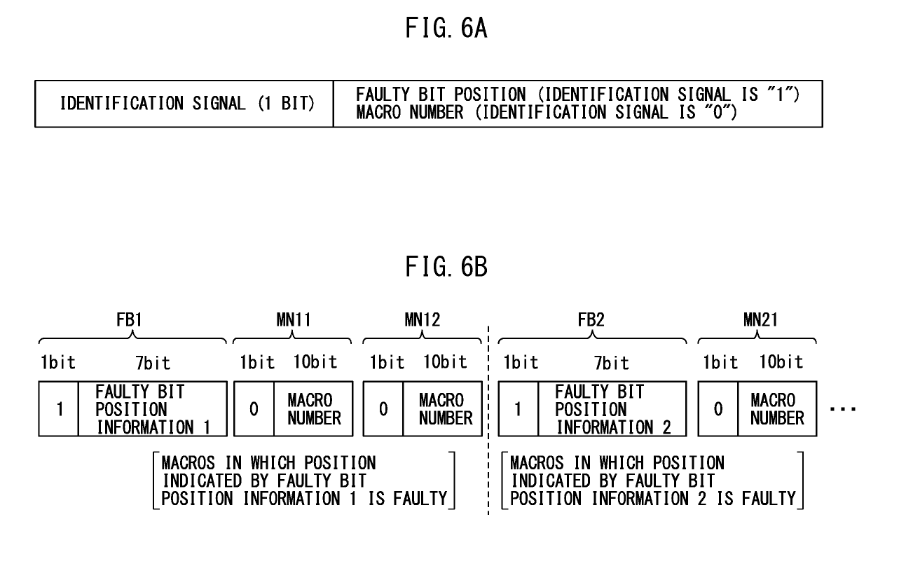

Hereinafter, embodiments of a redundancy information compression method and a semiconductor device of the exemplary embodiments will be described in detail with reference to the accompany drawings. FIG. 6A and FIG. 6B are diagrams for illustrating a first exemplary embodiment of the redundancy information compression method.

FIG. 6A illustrates an arrangement of an identification signal (a 1-bit signal) and a faulty bit position (for example an identification signal is “1”) or a macro number (for example the identification signal is “0”) for one SRAM macro; FIG. 6B illustrates an example of an arrangement for a plurality of SRAM macros.

In the redundancy information compression method of the first exemplary embodiment illustrated in FIG. 6A and FIG. 6B, redundancy information is represented by arranging a 1-bit identification signal and a 7-bit faulty bit position (which is set when the identification signal is “1”) or a 10-bit macro number (which is set when the identification signal is “0”), for example.

Assume, for example, that the capacity of each SRAM macro is 4 kw×128 bits=512 Kbits and the number of SRAM macros packaged is 1024, as described with reference to FIG. 2. Note that the number of faulty bits (the number of macros for which redundancy is performed) is about 50 or less.

A faulty bit position (a position in which an SRAM cell fails) that is common to the SRAM macros is one of the 128 positions and is represented by 7 bits (2⁷=128), for example. On the other hand, the macro number of each SRAM macro is one of 1024 macro numbers and is represented by 10 bits (2¹⁰=1024), for example.

In other words, in the redundancy information compression method of the first exemplary embodiment, the identification signal is first set to “1” to allow a faulty bit position to be set and then “faulty bit position information 1” is set using 7-bit faulty bit position information (faulty bit position) as illustrated in FIG. 6B (FB1).

Then the identification signal is set to “0” to allow a macro number to be set and a faulty macro (SRAM macro) in which the same position that is indicated by the “faulty bit position information 1” is faulty is set by a 10-bit macro number (MN11).

When there is another macro in which the same position that is indicated by “faulty bit position information 1” is faulty, the identification signal is set to “0” to allow a macro number to be set. Then the macro (macro that is not MN11) in which the same position that is indicated by “faulty bit position information 1” is faulty is set using a 10-bit macro number (MN12). Note that when there is yet another macro in which the same position that is indicated by “faulty bit position information 1” is faulty, the identification signal is set to “0” to allow a macro number to be set and the same process is repeated.

Then, when there is not another macro in which the same position indicated by “faulty bit position information 1” is faulty, the identification signal is set to “1” to allow a faulty bit position to be set and “faulty bit position information 2” is set using 7-bit faulty bit position information (FB2).

Then, the identification signal is set to “0” to allow a macro number to be set and a macro in which the same position that is indicated by “faulty bit position information 2” is faulty is set by using a 10-bit macro number (MN21). This process is repeated in sequence for all faulty bit positions where faulty bits exist among the 128 bit positions, for example.

Since the number of faulty bits that can occur is likely to be about 50 or less, a higher compression ratio can be achieved by compression processing based on up to 128 faulty bit positions than by compression processing based on 1024 macro numbers. Since the number of RAM macros packaged in a semiconductor chip will further increase in the future, this compression method will be able to achieve higher compression rates.

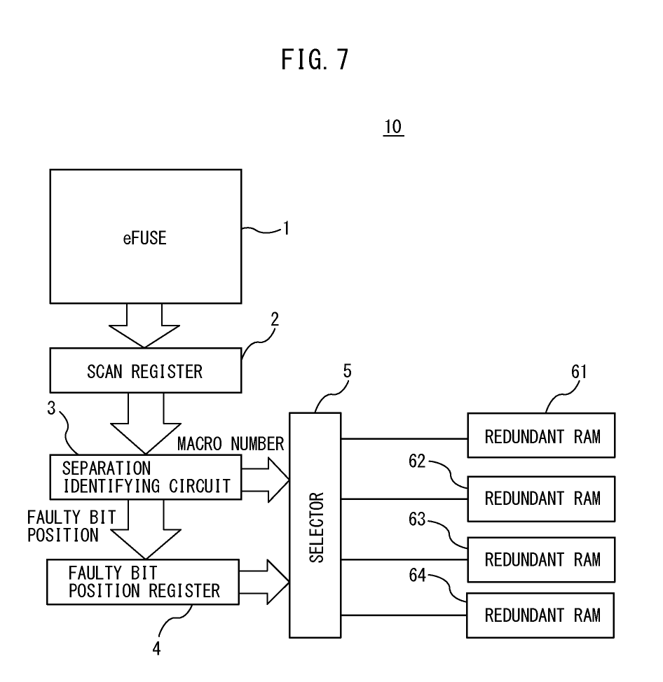

FIG. 7 is a block diagram illustrating an example of a semiconductor device to which the redundancy information compression method illustrated in FIG. 6A and FIG. 6B is applied and focusing on components that perform the redundancy processing in an embedded SRAM (semiconductor storage device), which is an example of a semiconductor device.

As illustrated in FIG. 7, the semiconductor device 10 includes an electronic fuse (eFUSE: a redundancy information storage unit) 1, a scan register 2, a separation identifying circuit 3, a faulty bit position register 4, a selector 5 and SRAM macros 61-64.

The electronic fuse 1, the scan register 2, the selector 5 and the SRAM macros 61-64 correspond to the electronic fuse 101, the scan register 102, the selector 105 and the SRAM macros 161-164 in the semiconductor device 100 described previously and illustrated in FIG. 4.

The electronic fuse 1 stores compressed redundancy information for SRAM macros for which redundancy processing as illustrated in FIG. 6A and FIG. 6B, for example, is performed. The scan register 2 reads and holds the compressed redundancy information stored in the electronic fuse 1 in sequence.

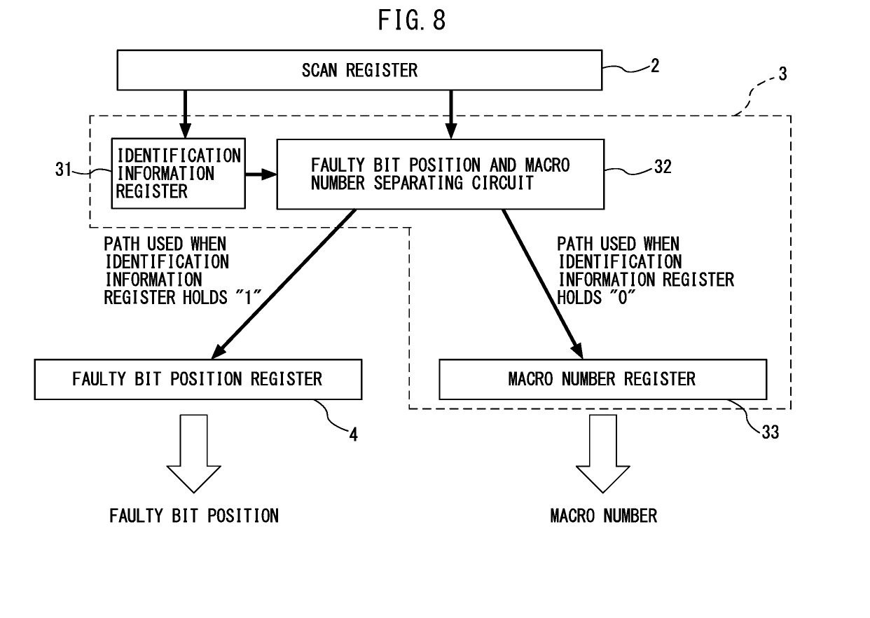

FIG. 8 is a diagram for illustrating a relevant part of the semiconductor device illustrated in FIG. 7 and illustrates the scan register 2, the separation identifying circuit 3 and the faulty bit position register 4 extracted from FIG. 7. The separation identifying circuit 3 and the faulty bit position register 4 form a redundancy information decompression unit which decompresses compressed redundancy information read from the electronic fuse 1 through the scan register 2.

The separation identifying circuit 3 receives an output (compressed redundancy information) from the scan register 2 and outputs a macro number and outputs faulty bit position information through the faulty bit position register 4.

In other words, the separation identifying circuit 3 includes an identification information register 31, a faulty bit position and macro number separating circuit 32, and a macro number register 33. The identification information register 31 holds a 1-bit identification signal, for example. Note that when the identification signal is “1”, for example, a faulty bit position is allowed to be set whereas when the identification signal is “0”, a macro number is allowed to be set, as has been described previously.

The faulty bit position and macro number separating circuit 32 receives an output from the scan register 2 and, when the identification information register holds “1”, outputs a faulty bit position (faulty bit position information) through the faulty bit position register 4. When the identification information register holds “0”, the faulty bit position and macro number separating circuit 32 outputs a macro number through the macro number register 33.

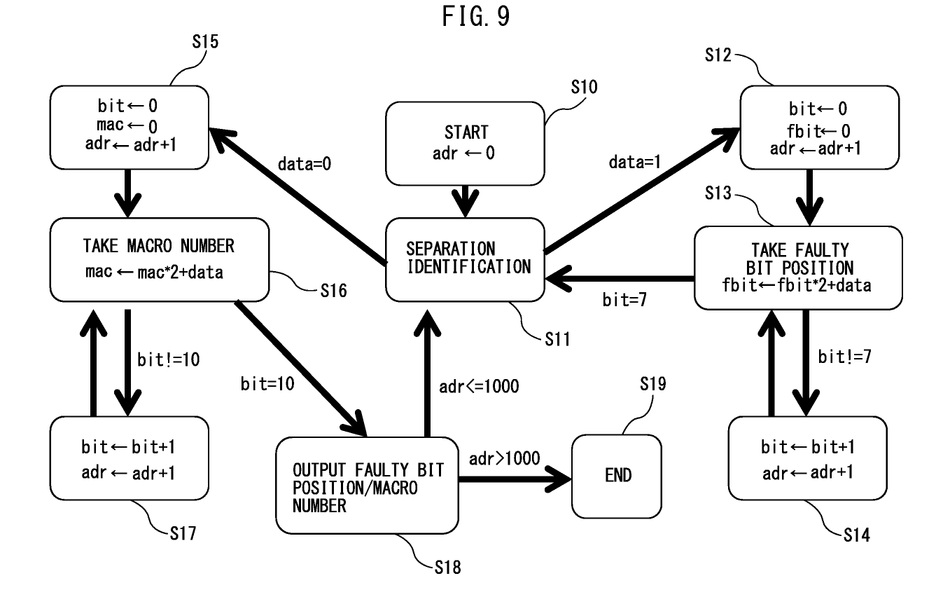

FIG. 9 is a state transition diagram illustrating an example of the separation identifying circuit of the semiconductor device illustrated in FIG. 7 and FIG. 8. First, the process starts in state S10, sets address adr to “0” (adr←0) and proceeds to state S11, where a separation identification process is performed.

In state S11, when the first data (bit 1) is “1” (data=1), for example, the identification information register holds “1” and the process proceeds to state S12. In state S12, bit is set to “0” (bit←0), faulty bit position fbit is set to “0” (fbit←0), and the address is incremented by “+1” (adr←adr+1).

Then in state S13, the position of a faulty bit is taken. In other words, fbit is shifted by one digit in binary as fbit←fbit*2+data in state S13, bit←bit+1 and adr←adr+1 operations are performed in state S14, and the process is repeated until bit=7 is reached. The position where a faulty cell (SRAM cell) exists is set by this 7-bit faulty bit position (faulty bit position information) and then the process returns to state S11.

When the first data (bit 1) is “0” (data=0) in state S11, the identification information register holds “0” and the process proceeds to state S15. In state S15, bit is set to “0” (bit←0), macro number mac is set to “0” (mac←0), and the address is incremented by “+1” (adr←adr+1).

Then, a macro number is taken in state S16. In other words, mac is shifted by one digit in binary as mac←mac*2+data in state S16, bit←bit+1 and adr←adr+1 operations are performed in state S17, and the process is repeated until bit=10 is reached. When bit=10, the process returns to state S11 through state S18.

A macro where the same position as the faulty bit position set in state S13 (S12-14) is faulty is set by this 10-bit macro number. Note that when there are a plurality of macros in which the same bit position is faulty, the same number of bit strings in which the data at bit 1 is set to “0” (the identification information register holds “0”) for macro number setting as the number of the plurality of macros are successively produced.

Then when the address is not greater than 1000, for example, in state S18 (adr≦1000), the faulty bit position information and the macro number information are output to the SRAM macros 61-64 through the selector 5. When the address is greater than 1000 (adr>1000), the process is terminated (state S19).

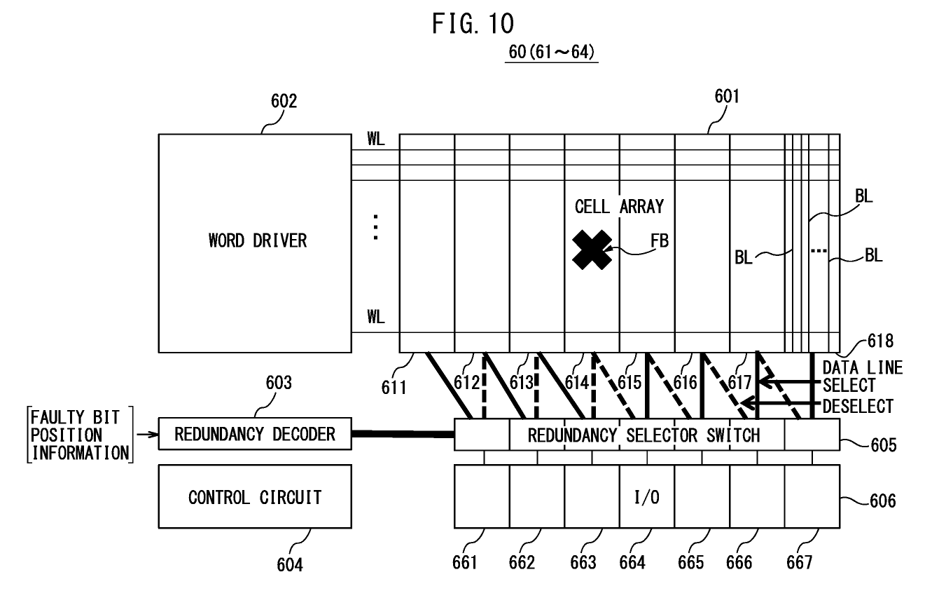

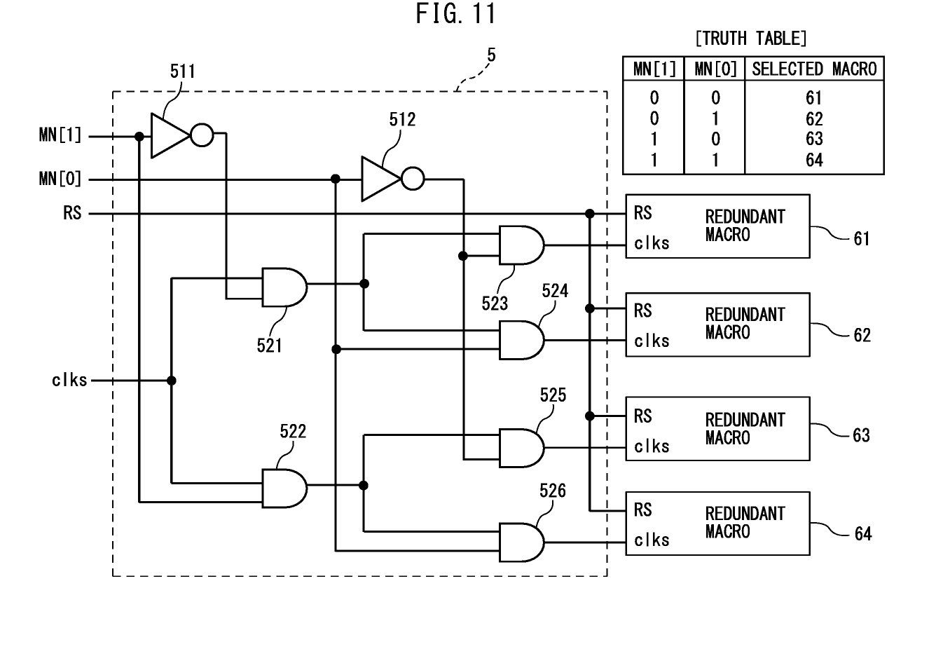

FIG. 10 is a block diagram illustrating an example of an SRAM macro in the semiconductor device illustrated in FIG. 7 and illustrates an SRAM macro for which I/O redundancy is performed. Note that the SRAM macros 61-64 described previously and illustrated in FIG. 7 have the same configuration and the SRAM macro 60 will be described here as a representative of the SRAM macros.

As illustrated in FIG. 10, the SRAM macro 60 includes a memory cell array 601, a word driver 602, a redundancy decoder 603, a control circuit 604, a redundancy selector switch 605, and an I/O unit (input/output circuit) 606.

The I/O unit 606 includes seven I/O terminals 661-667 and the memory cell array 601 includes eight memory units 611-618, which are one more than the number of the I/O terminals, for example, so that redundancy can be performed when any one of the memory units includes a faulty bit. Note that a plurality of bit lines are provided for each of the memory units 611-618.

FIG. 10 illustrates an example in which the memory unit 614 includes a faulty memory cell (faulty bit). In this case, the redundancy selector switch 605 makes switching to connect the memory units 611-613 to the I/O terminals 661-663 and to prevent the memory unit 614 from being used, in accordance with an output from the redundancy decoder 603.

In other words, faulty bit position information (a redundancy signal RS) is input from the selector 5 to the redundancy decoder 603 to cause I/O redundancy to be performed so that the memory unit 614 corresponding to the faulty bit position is not used.

Note that a signal indicating a macro number (corresponding to a signal MN[0] and MN[1] in FIG. 11, for example) from the selector 5 is used to select the SRAM macro (redundant RAM) for which the redundancy processing is performed.

While FIG. 10 illustrates an example of I/O redundancy, column redundancy using one or more bit lines as a unit, or row redundancy using one or more word lines as a unit, or any other known redundancy may be used.

FIG. 11 is a block diagram illustrating an example of the selector in the semiconductor device illustrated in FIG. 7, which is configured to select any one of four SRAM macros 61-64 in accordance with a 2-bit signal MN[0], MN[1], which indicates a macro number.

In particular, when 2-bit signal MN[0], MN[1] is “0, 0”, for example, a clock signal clks for the SRAM macro 61 is activated to select the SRAM macro 61 and the clock signal clks for the other SRAM macros 62-64 is blocked to deselect the SRAM macros 62-64.

Furthermore, when the 2-bit signal MN[0], MN[1] is “0, 1”, for example, the clock signal clks for the SRAM macro 62 is activated to select the SRAM macro 62; when the 2-bit signal MN[0], MN[1] is “1, 0”, the clock signal clks for the SRAM macro 63 is activated to select the SRAM macro 63.

When the 2-bit signal MN[0], MN[1] is “1, 1”,for example, the clock signal clks for the SRAM macro 64 is activated to select the SRAM macro 64 and the clock signal clks for the other SRAM macros 61-63 is blocked to deselect the SRAM macros 61-63.

Note that the redundancy signal RS (faulty bit position information) is always input into all of the SRAM macros 61-64. The selector 5 illustrated in FIG. 11 is illustrative only and various variations and modification can be made, of course.

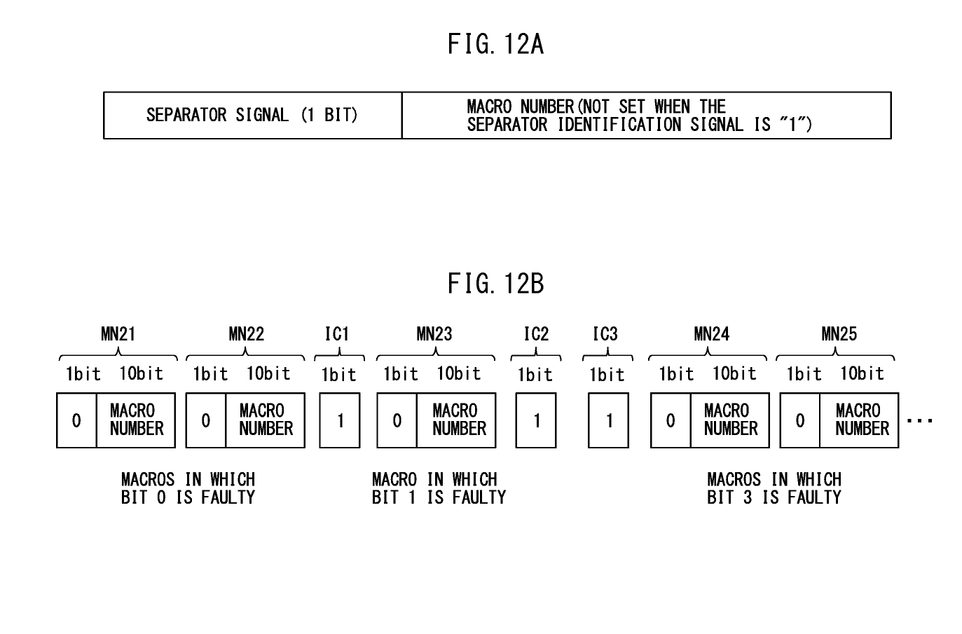

FIG. 12A and FIG. 12B are diagrams for illustrating a second exemplary embodiment of the redundancy information compression method. FIG. 12A illustrates an arrangement of a separator signal (a 1-bit signal) and a macro number (which is set when the separator signal is “0”) and FIG. 12B illustrates an example of an arrangement for a plurality of SRAM macros.

In the redundancy information compression method of the second exemplary embodiment illustrated in FIG. 12A and FIG. 12B, redundancy information is represented by arranging a 1-bit separator signal and a 10-bit macro number (which is set when the identification signal is “0”), for example.

In the redundancy information compression method of the first exemplary embodiment described previously, redundancy information is compressed by organizing together (arranging in an ordered way) macro numbers of macros with a faulty bit in the same position on the basis of position information indicating positions where faulty bit has occurred (faulty bit position information).

In the redundancy information compression method of the second exemplary embodiment, on the other hand, faulty bit position information is separated (incremented) by a separator signal of “1” and macro numbers of macros having a faulty bit in the same position are arranged between the separated bit strings.

For example, when the separator signal (identification signal) is “0”, a macro number is allowed to be set and a macro in which the same position that is indicated by the set “faulty bit position information” is faulty is set by a 10-bit macro number.

In other words, in the redundancy information compression method of the second exemplary embodiment, since the separator signal (identification signal) is “0” as illustrated in FIG. 12B, first a macro in which bit 0 is faulty is set by a 10-bit macro number (MN21). Then, a macro in which the same bit 0 is faulty is set by a 10-bit macro number with the separator signal “0” (MN22).

Then, since the separator signal is “1” at IC1, faulty bit position information is incremented and faulty bit position information in which bit 1 is faulty is set. A macro in which bit 1 is faulty is set by MN23 (with separator signal “0” and a 10-bit macro number).

Furthermore, since the separator signal is “1” at IC2, faulty bit position information is incremented and faulty bit position information in which bit 2 is faulty bit is set. Since there is not a macro in which bit 2 is faulty in the example in FIG. 12B, the faulty bit position information is further incremented by IC3 at which the separator signal is “1” and faulty bit position information in which bit 3 is faulty is set.

Then, macros in which bit 3 is faulty are set by MN24 (with separator signal “0” and a 10-bit macro number) and MN25 (with separator signal “0” and a 10-bit macro number).

In this way, according to the redundancy information compression method of the second exemplary embodiment, faulty bit position information can be set by sequentially incrementing by a 1-bit separator signal (“1”) without using 7 bits, for example, for setting faulty bit position information.

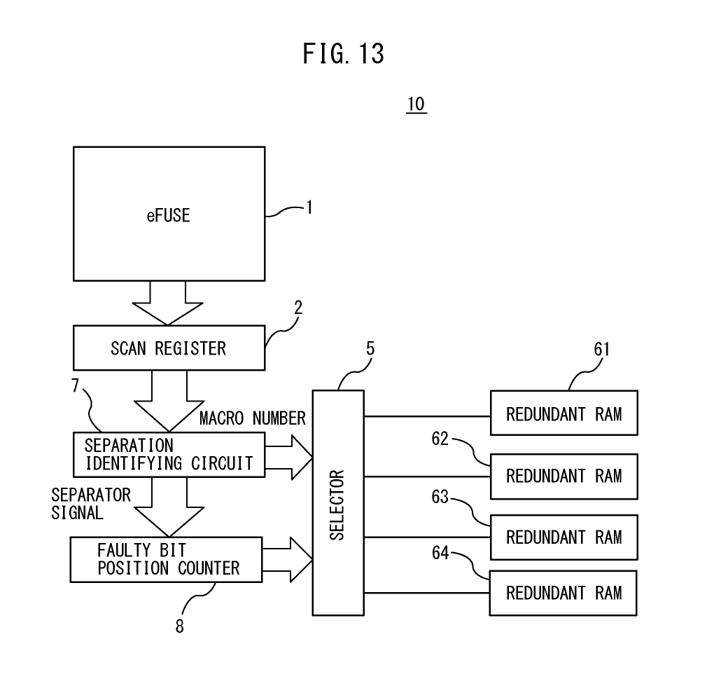

FIG. 13 is a block diagram illustrating an example of a semiconductor device to which the redundancy information compression method illustrated in FIG. 12A and FIG. 12B is applied. FIG. 13 focuses on components that perform redundancy processing in an embedded SRAM (semiconductor storage device), which is an example of a semiconductor device.

As illustrated in FIG. 13, the semiconductor device 10 includes an electronic fuse 1, a scan register 2, a separation identifying circuit 7, a faulty bit position counter 8, a selector 5 and SRAM macros 61-64. The electronic fuse 1, the scan register 2, the selector 5 and the SRAM macros 61-64 are similar to those described previously and illustrated in FIG. 7.

The electronic fuse 1 stores compressed redundancy information for SRAM macros for which redundancy processing as illustrated in FIG. 12A and FIG. 12B, for example, is performed. The scan register 2 reads and holds the compressed redundancy information stored in the electronic fuse 1 in sequence.

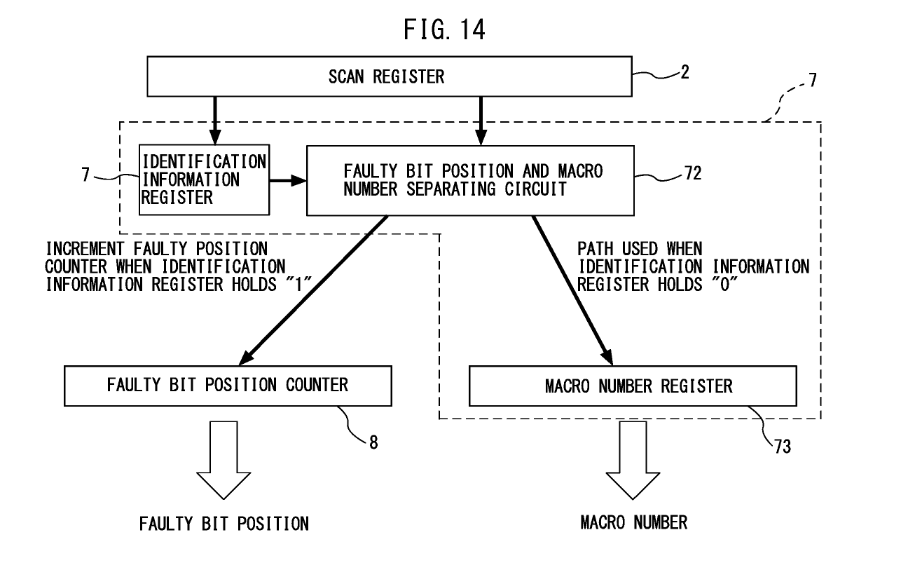

FIG. 14 is a diagram for illustrating a relevant part of the semiconductor device illustrated in FIG. 13 and illustrates the scan register 2, the separation identifying circuit 7 and the faulty bit position counter 8 extracted from FIG. 13. The separation identifying circuit 7 and the faulty bit position counter 8 form a redundancy information decompression unit which decompresses compressed redundancy information read from the electronic fuse 1 through the scan register 2.

The separation identifying circuit 7 receives an output (compressed redundancy information) from the scan register 2 and outputs a macro number and outputs faulty bit position information through the faulty bit position counter 8.

In other words, the separation identifying circuit 7 includes an identification information register 71, a faulty bit position and macro number separating circuit 72, and a macro number register 73. The identification information register 71 holds a 1-bit separator signal (identification signal), for example.

Note that, as described previously, when the separator signal is “1”, for example, faulty bit position is allowed to be incremented (+1) and set; when the separator signal (identification signal) is “0”, a macro number is allowed to be set.

In other words, when the identification information register holds “1”, an increment signal (for example a signal of “1”) is output from the faulty bit position and macro number separating circuit 72 to the faulty bit position counter 8, which in turn increments a faulty bit position (+1).

When the identification information register holds “0”, a macro number is output through the macro number register 73 in the same way as described with reference to FIG. 7. Note that the faulty bit position (faulty bit position information) from the faulty bit position counter 8 and the macro number from the macro number register 73 are input into the selector 5. The SRAM macros 61-64 and the selector 5 illustrated in FIG. 13 have configurations similar to the configurations of those described with reference to FIG. 10 and FIG. 11, for example.

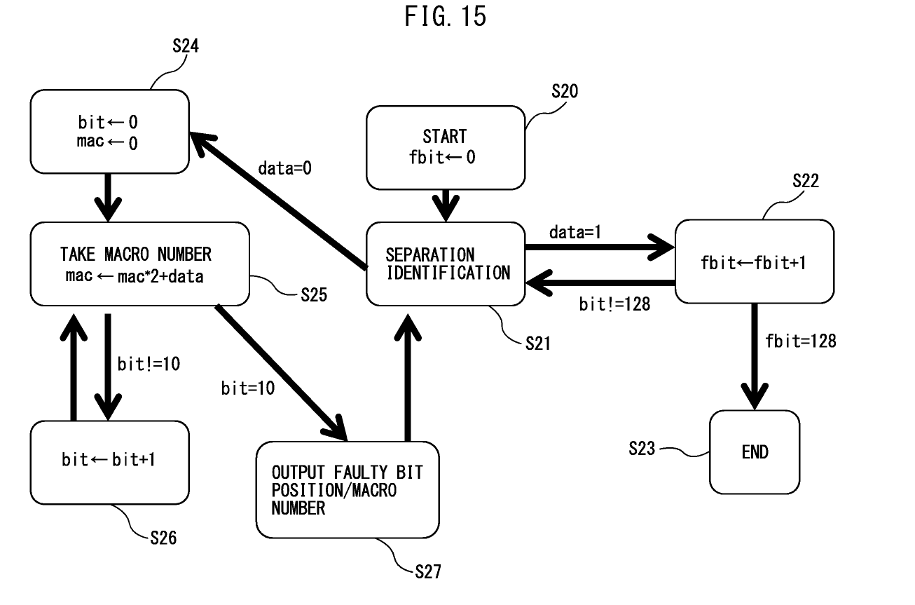

FIG. 15 is a state transition diagram for illustrating an example of the separation identifying circuit in the semiconductor device illustrated in FIG. 13 and FIG. 14. First, the process starts in state S20, sets faulty bit position fbit to “0” (fbit←0) and then proceeds to state S21, where a separation identification process is performed.

In state S21, when the first data (bit 1) is “1” (data=1), for example, the identification information register holds “1” and the process proceeds to state S22. In state S22, the faulty bit position fbit is incremented by “+1” (fbit←fbit+1) and, when the faulty bit position fbit is not 128, the process returns to state S21; when fbit is 128, the process is terminated (state S23).

Note that “128” is all position information of faulty bits in each SRAM macro (the number of positions that can be faulty 2⁷=128 positions (bits)), for example, as described previously and can be changed as appropriate in accordance with specifications.

When the first data (bit 1) is “0” (data=0) in state S21, the identification information register holds “0” and the process proceeds to state S24. In state 24, the bit is set to “0” (bit←0), the macro number mac is set to “0” (mac←0), and then the process proceeds to state S25.

In state S25, mac is shifted by one digit in binary as mac←mac*2+data and a macro number is taken. Then the operation of bit←bit+1 is performed in state S26 and the process is repeated until bit=10 is reached. When bit=10, the process returns to state S21 through state S27.

By this 10-bit macro number, a macro in which the same position that is indicated by the faulty bit position set in state S22 is faulty is set. Note that when a plurality of macros in which a set faulty bit position is not faulty appear successively, the same number of bit strings in which data at bit 1 is “1” (the identification information register holds “1”) and a faulty bit position is incremented one by one as the number of the macros are successively produced.

In this way, according to the second exemplary embodiment, faulty bit position information can be set by sequentially incrementing a faulty bit position that is set using 7 bits, for example, simply by setting the initial data to “1” (1 bit). Thus, the second exemplary embodiment has the advantageous effect of compressing a large amount of redundancy information when faulty bits in macros are distributed over many different bit positions.

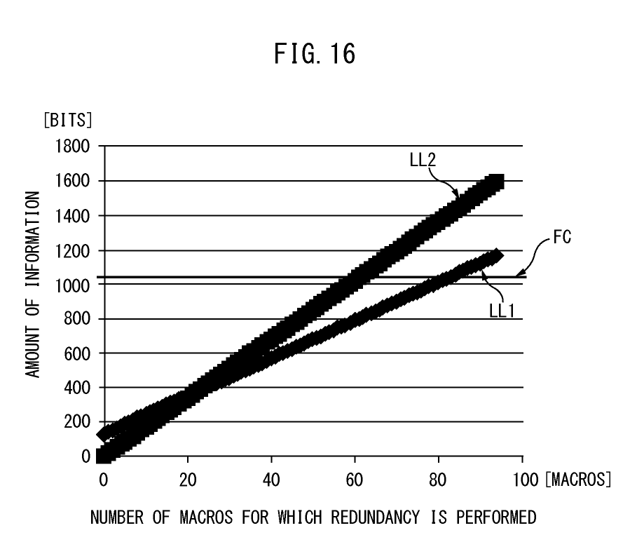

FIG. 16 is a graph for illustrating the advantageous effect of the redundancy information compression method of the second exemplary embodiment and is used for comparing the redundancy information compression method of the second exemplary embodiment with the redundancy information compression method described with reference to FIG. 3B. In FIG. 16, the horizontal axis represents the number of macros (SRAM macros) for which redundancy is performed and the vertical axis represents the amount of compressed redundancy information (bits) stored in an electronic fuse (eFUSE).

Symbol LL1 indicates a characteristic of the redundancy information compression method of the second exemplary embodiment, LL2 indicates a characteristic of the redundancy information compression method described with reference to FIG. 3B, and FC indicates the capacity (1024 bits) of the electronic fuse of one macro.

A case is assumed in which the capacity of an SRAM macro is 4 kw×128 bits=512 Kbits, for example, as in the example described previously and the number of SRAM macros packaged is 1024, for example.

As can be seen from the comparison between LL1 and LL2 in FIG. 16, when the number of SRAM macros for which redundancy is performed exceeds about 20, for example, the efficiency of compression by the redundancy information compression method of the second exemplary embodiment increases with increasing number of SRAM macros.

Specifically, when the number of SRAM macros is 0 (when there is no faulty bit and redundancy does not need to be performed), for example, the amount of information stored in the electronic fuse is 127 bits in the second exemplary embodiment while 0 bits in the example in FIG. 3B.

However, in the semiconductor manufacturing technology in reality, the number of SRAM macros for which redundancy is performed is approximately 50 out of 1024 SRAM macros, for example. It is conceivable that further microfabrication and further increase in integration density in the future will increase the number of SRAM macros packaged.

Thus, it can be seen that the redundancy information compression method of the second exemplary embodiment can address as many as about 80 SRAM macros even when the capacity of the electronic fuse in one SRAM macro is 1024 bits, for example.

As has been described in detail above, the redundancy information compression method and semiconductor device of this exemplary embodiment can further compress redundancy information to reduce the redundancy information storage area (the area of the electronic fuse) in a semiconductor chip.

In other words, when many macros are packaged, the method can improve ratio of compression of redundancy data, reduce the number of electronic fuses to reduce the size of a semiconductor chip or, increase the number of successful redundancy repairs to improve the yields with the same number of electronic fuses.

Note that the redundancy processing in this exemplary embodiment may be I/O redundancy using I/O as a unit, a column redundancy using one or more bit lines as a unit, a row redundancy using one or more word lines as a unit, or any of various other known types of redundancy processing.

Furthermore, this exemplary embodiment is not limited to application to an embedded SRAM made up of a plurality of SRAM macros. For example, this exemplary embodiment can be applied to a wide variety of semiconductor storage devices including a plurality of memory macros, such as DRAMs, for example. Moreover, the exemplary embodiments can be applied not only to semiconductor storage devices including a plurality of memory macros but also to various semiconductor devices including a plurality of circuit macros having an identical configuration, for example.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations can be made hereto without departing from the spirit and scope of the invention.

What is claimed is:

1. A redundancy information compression method configured to compress redundancy information among a plurality of macros for which redundancy processing is performed, comprising:
setting faulty bit position information, included in the redundancy information, for a macro of the plurality of macros including a faulty bit, the faulty bit position information indicating a position of the faulty bit included in the macro; and
organizing macro numbers, included in the redundancy information, of macros of the plurality of macros having the same faulty bit position information as the set faulty bit position information together.

2. The redundancy information compression method according to claim 1, wherein
the macro number is represented by a first bit string identifying one of the plurality of macros,
the faulty bit position information is represented by a second bit string identifying the faulty bit in each of the macros, and
the first bit string is greater than the second bit string.

3. The redundancy information compression method according to claim 1, wherein
the setting of the faulty bit position information is made by the second bit string from the macro including the faulty bit.

4. The redundancy information compression method according to claim 3, wherein
the setting of the faulty bit position information is made by the second bit string after the first identification signal of a multibit string to a first value, and
the organizing macro numbers together is set by the first bit string after setting the first identification signal of a multibit string to a second value.

5. The redundancy information compression method according to claim 1, wherein
the setting of the faulty bit position information is made by incrementing the faulty bit position information in sequence.

6. The redundancy information compression method according to claim 5, wherein
the setting of the faulty bit position information is made by setting the first identification signal of a multibit string to a first value to increment the faulty bit position information, and
the organizing the macro numbers together is set by the first bit string after setting the first identification signal of a multibit string to a second value.

7. A semiconductor device comprising:
a plurality of macros for which redundancy processing can be performed;
a redundancy information storage unit storing redundancy information compressed by a redundancy information compression method configured to compress redundancy information among the plurality of macros; and
a redundancy information decompression unit, wherein
the redundancy information compression method includes:
setting faulty bit position information, included in the redundancy information, for a macro of the plurality of macros including a faulty bit, the faulty bit position information indicating a position of the faulty bit included in the macro; and
organizing macro numbers, included in the redundancy information, of macros of the plurality of macros having the same faulty bit position information as the set faulty bit position information together, and wherein
the redundancy information decompression unit is configured to receive the compressed redundancy information from the redundancy information storage unit and to output the faulty bit position information and the macro number corresponding to the faulty bit position information.

8. The semiconductor device according to claim 7, wherein
the semiconductor device further includes:
a scan register configured to receive the compressed redundancy information from the redundancy information storage unit and to output the compressed redundancy information to the redundancy information decompression unit.

9. The semiconductor device according to claim 7, wherein
the semiconductor device further includes:
a selector receiving an output from the redundancy information decompression unit and selecting a macro for which redundancy processing is performed.

10. The semiconductor device according to claim 7, wherein
the redundancy information decompression unit further includes:
a separation identifying circuit, wherein the separation identifying circuit includes:
an identification information register configured to determine whether the first identification signal of the multibit string is set to the first value or the second value; and
a first faulty bit position and macro number separating circuit configured to output the faulty bit position information from the second bit string following the identification signal when the identification signal is set to the first value, and to output the macro number from the first bit string following the identification signal when the identification signal is set to the second value.

11. The semiconductor device according to claim 10, wherein
the redundancy information decompression unit further includes:
a macro number register configured to hold and output the macro number from the faulty bit position and macro number separating circuit when the identification signal is set to the second value; and
a faulty bit position register configured to hold and output the faulty bit position from the faulty bit position and macro number separating circuit when the identification signal is set to the first value.

12. The semiconductor device according to claim 7, wherein
the redundancy information decompression unit includes:
a separation identifying circuit, and wherein the separation identifying circuit includes:
an identification information register configured to determine whether the first identification signal of the multibit string is set to the first value or the second value; and
a faulty bit position and macro number separating circuit configured to increment the faulty bit position information in sequence when the identification signal is set to the first value, and to output the macro number from the first bit string following the identification signal when the identification signal is set to the second value.

13. The semiconductor device according to claim 12, wherein
the redundancy information decompression unit further includes:
a macro number register configured to hold and output the macro number from the faulty bit position and macro number separating circuit when the identification signal is set to the second value; and
a faulty bit position counter configured to increment and output the faulty bit position in accordance with an increment signal from the faulty bit position and macro number separating circuit when the identification signal is set to the first value.

14. The semiconductor device according to claim 7, wherein
the redundancy information storage unit is an electronic fuse,
the macros are SRAM macros, and
each of the SRAM macros includes an identical circuit configuration.

15. The semiconductor device according to claim 14, wherein
the redundancy processing is I/O redundancy performed using an I/O as a unit.
